(19) United States
(12) Patent Application Publication
(10) Pub. No.: US 2010/0051903 A1
(43) Pub. Date: Mar. 4, 2010

(54) METHOD OF ALIGNING NANORODS AND RELATED COMPOSITIONS

(76) Inventor: Seo-Yong Cho, Seoul (KR)

Correspondence Address: Seo-Yong Cho;San 4-2, Bongchun-Dong, Gwanak-GU, Seoul, 151-818, KR

(21) Appl. No.: 12/200,524

(22) Filed: Aug. 28, 2008

(51) Int. Cl. H01L 29/06; B05D 7/00; H01B 1/08; H01L 21/20

(52) U.S. Cl. 257/14; 427/180; 252/518.1; 252/519.5; 252/520.1; 252/520.21; 252/521.1; 252/521.2; 252/500; 252/519.4; 252/520.5; 252/512; 438/478; 257/E29.07; 257/E21.09; 977/762; 977/890

(57) ABSTRACT

A method of forming an array of nanorods on a crystalline substrate includes heating a composition that includes the crystalline substrate, a nanorod precursor, and a surfactant. The surfactant is capable of associating with the surface of the nanorods. The resulting nanostructures formed from the methods may be used in a variety of devices, including dye-sensitizing solar cell devices.

### BACKGROUND

One-dimensional nanostructures such as nanorods, nanowires and nanofibres exhibit a wide range of electrical and optical properties that depend on size and shape. Nanostructures including conductors and/or semiconductors may find use in electronics, optical and optoelectronic devices. Such devices include sensors, transistors, detectors, and light-emitting diodes. However, methods for forming one-dimensional nanostructures can be complicated, time-consuming, and expensive, requiring multiple synthetic steps and numerous reactants.

### SUMMARY

In one embodiment, a method of forming an array of nanorods on a crystalline substrate is provided, including heating a composition comprising the crystalline substrate, a nanorod precursor, and a surfactant, wherein nanorods are formed on the substrate and the surfactant associates with the surface of the nanorods. The composition may be formed by combining the crystalline substrate with a solution comprising the nanorod precursor and the surfactant. The solution may be formed by combining the nanorod precursor and the surfactant. The surfactant may be removed from the surface of the nanorods, and the heating may be carried out in an autoclave reactor at, for example, a temperature of about 90° C. or greater. The surface of the substrate may be is lattice-matched to the nanorods. The substrate may comprise a conducting metal oxide, which may be selected from the group consisting of SnO₂, CdO, ZnO, indium-tin-oxide (ITO), F:SnO₂ (FTO), Al-doped zinc oxide (AZO), Zn-doped indium oxide (IZO), Ga-doped indium oxide (GZO), Nb:SrTiO₂, sapphire, Nb:TiO₂, (La_{0.5}Sr_{0.5})CoO₃ (LSCO), La_{0.7}Sr_{0.3}MnO₃ (LSMO), SrRuO₃ (SRO), Sr₃Ru₂O₇, and Sr₄Ru₃O₁₀. The substrate may also comprise a semiconductor, which may be selected from the group consisting of undoped or doped titanium oxide, zinc oxide, tungsten oxide, tin oxide, antimony oxide, niobium oxide, indium oxide, barium titanate, strontium titanate, and cadmium sulfide. The substrate may have a cubic, tetragonal or orthogonal crystalline lattice, and the surfactant may comprise an amine derivative surfactant. The distance between adjacent nanorods may range from about 5 nm to about 100 nm, and the diameter of the nanorods may range from about 5 nm to about 1 μm. The length of the nanorods may range from about 10 nm to about 10 μm. The nanorods may also comprise a semiconductor, which may be selected from the group consisting of undoped or doped titanium oxide, metatitanic acid, orthotitanic acid, titanium hydroxide, zinc oxide, tungsten oxide, tin oxide, antimony oxide, niobium oxide, indium oxide, barium titanate, strontium titanate, and cadmium sulfide. The substrate may comprise (0001) sapphire and the nanorods may comprise ZnO. The substrate may also comprise (01-12) sapphire and the nanorods may also comprise WO₃. In addition, the substrate may comprise (001) Nb:SrTiO₂ and the nanorods may comprise TiO₂. A layer of dye may be formed on the surface of the nanorods.

In another embodiment, a composition is provided comprising the crystalline substrate, the nanorod precursor and the surfactant. This composition may further comprise an array of nanorods disposed on a surface of the crystalline substrate. The substrate may comprise a conducting metal oxide, which may be selected from the group consisting of SnO₂, CdO, ZnO, indium-tin-oxide (ITO), Al-doped zinc oxide (AZO), Zn-doped indium oxide (IZO), Nb: SrTiO₂, sapphire, Nb:TiO₂, (La_{0.5}Sr_{0.5})CoO₃ (LSCO), La_{0.7}Sr_{0.3}MnO₃ (LSMO), SrRuO₃ (SRO), Sr₃Ru₂O₇, and Sr₄Ru₃O₁₀. The nanorods may comprise a semiconductor, which may be selected from the group consisting of doped or undoped titanium oxide, zinc oxide, tungsten oxide, tin oxide, antimony oxide, niobium oxide, indium oxide, barium titanate, strontium titanate, and cadmium sulfide. The composition may further comprise a dye adsorbed on the surface of the nanorods.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 depicts an illustrative embodiment of a method of forming an array of TiO₂ nanorods on Nb-doped SrTiO₃ substrate: (a) TiO₂ precursors and single crystalline Nb:SrTiO₃ (001) substrates which have an epitaxial relationship with TiO₂ (001) plane are put into a hydrothermal reactor; (b) TiO₂ nanocrystals are heterogeneously nucleated on the Nb:SrTiO₃ (001) substrates after heating the hydrothermal reactor; (c) The addition of surfactant induces the 1-dimensional growth of TiO₂ nanoparticles with <001> direction thereby growing the TiO₂ nanorods on the substrate; (d) Since the TiO₂ nanorods and the Nb:SrTiO₃ (001) substrate have epitaxial relationship, the TiO₂ nanorods are grown with the out-of-plane direction.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

The present technology relates to methods of forming arrays of nanorods on crystalline substrates. The methods are simple, quick, and relatively inexpensive compared to conventional methods. Essentially, the arrays of nanorods are formed by combining all relevant reactants and heating the resulting composition. The methods do not require any pretreatment of the substrate or any seed material for growing the nanorods. Also disclosed are nanostructures formed by the disclosed methods and devices incorporating the nanostructures.

The method of forming an array of nanorods on a crystalline substrate involves heating a composition comprising the crystalline substrate, a nanorod precursor, and a surfactant. The composition may be an aqueous solution or may comprise an organic solvent.

The substrate may be any crystalline substrate including a single crystalline substrate that is lattice-matched to the nanorods arrayed thereon. A variety of crystalline substrates may be used with the disclosed methods. Examples of substrates include, but are not limited to a conductor, a conducting metal oxide, a semiconductor, a non-conductor, and the like. A variety of conducting metal oxides may be used, including, but not limited to SnO₂, CdO, ZnO, indium-tin-oxide (ITO), F:SnO₂ (FTO), Al-doped zinc oxide (AZO), Zn-doped indium oxide (IZO), Ga-doped indium oxide (GZO), Nb : SrTiO₂, sapphire, Nb:TiO₂, (La_{0.5}Sr_{0.5})CoO₃ (LSCO), La_{0.7}Sr_{0.3}MnO₃ (LSMO), SrRuO₃ (SRO), Sr₃Ru₂O₇, Sr₄Ru₃O₁₀, and the like. A variety of semiconductors may be used, including, but not limited to doped or undoped titanium oxide, zinc oxide, tungsten oxide, tin oxide, antimony oxide, niobium oxide, indium oxide, barium titanate, strontium titanate, and cadmium sulfide.

Besides composition, other characteristics of the crystalline substrates may vary. In some embodiments, the surface of the substrate is lattice-matched to the nanorods. In other embodiments, the substrate has a cubic, tetragonal, or orthogonal crystalline surface.

As noted above, the composition of the disclosed methods includes a surfactant that is capable of selectively associating with the peripheral surface of the nanorods. The term “selectively” used herein refers to the state where the surfactant associates with the side of the nanorods. The term “peripheral surface” used herein refers to the side surface of the nanorod, but not the top of the nanorods. The surfactant inhibits nanorod-growth on the sides of the nanorods, facilitating the one-dimensional growth of the nanorods from the surface of the substrate. A variety of surfactants may be used, including, but not limited to amine derivative surfactants. Non-limiting examples of amine derivative surfactants are ethylene diamine, ethanol amine, diethanol amine, triethanol amine, glutamic acid, aspartic acid, ethylenediaminetetraacetic acid, ethylenediaminetetraacetic acid disodium salt, ethylenediaminetetraacetic acid trisodium salt, ethylenediaminetetraacetic acid tetrasodium salt, hexamethylenetetramine, and the like.

The composition further comprises a nanorod precursor. Precursors for the formation of nanorods are well-known. By way of example only, the nanorod precursor may be a metal alkoxide, a metal halide, a metal hydroxide, or other organometallic compounds. Specific examples of nanorod precursors are provided in the Examples below.

The reaction conditions of the disclosed methods, including those involved in the heating step, may be chosen from those used in other well-known hydrothermal synthesis schemes. Hydrothermal synthesis involves the crystallization of substances from high-temperature aqueous solutions at high vapor pressure in a closed reactor. Crystallization may be performed in an apparatus consisting of a steel pressure vessel called autoclave. In some embodiments of the disclosed methods, the heating is carried out in an autoclave. In other embodiments, the heating is carried out at a temperature of about 90° C. or greater. In further embodiments, the heating is carried out at a temperature of about 90° C., 100° C., 110° C. or 120° C. The nanorods obtained by the methods disclosed herein may be further subject to general treatments used in hydrothermal synthesis.

The methods disclosed herein may include additional steps. In some embodiments, the methods further comprise forming any of the disclosed compositions by combining any of the disclosed crystalline substrates with a solution comprising any of the disclosed nanorod precursors and any of the disclosed surfactants. In other embodiments, the methods further comprise forming the solution of the nanorod precursor and the surfactant by combining any of the disclosed nanorod precursors and any of the disclosed surfactants.

In yet other embodiments, the methods further comprise removing the surfactant from the surface of the nanorods. The removal of the surfactant may be accomplished by a variety of techniques. In some embodiments, the surfactant is removed by washing the nanorods with a solvent. A variety of solvents may be used, including, but not limited to an alkaline solution, an acidic solution, or water. The nanorods may be washed one or more times.

In yet further embodiments, the methods further comprise forming a layer of dye on the surface of the nanorods. In some embodiments, the dye is absorbed to the surface of the nanorods. A variety of dyes may be used. In some embodiments, the dye is capable of absorbing visible light, infrared light, or both. In further embodiments, the dye comprises one or more metal complexes or one or more organic dyes. Non-limiting examples of the metal complexes include metal phthalocyanine, such as copper phthalocyanine and titanyl phthalocyanine, chlorophyll, hemin, ruthenium complex, such as ruthenium (II) complex having a dipyridophenazine or tetrapyridophenazine ligand, osmium complex, such as osmium complex having tetradentate polypyridine ligand, iron complex, such as iron complex having tetradentate polypyridine ligand and zinc complex, such as zinc complex having tetradentate polypyridine ligand. Non-limiting examples of organic dyes include metal-free phthalocyanine, cyanine dyes, merocyanine dyes, xanthene dyes and triphenylmethane dyes.

A variety of methods may be used to form a layer of dye on the surface of the nanorods. In one embodiment, the nanorods are dipped into a solution comprising the dye and an organic solvent at room temperature or under heating. Any solvent can be used, provided the dye is dissolved in the solvent. Non-limiting examples of the solvent include water, alcohol, toluene and dimethylformamide.

The disclosed methods are capable of providing arrays of nanorods with a variety of characteristics. In some embodiments, the distance between adjacent nanorods is at least 5 nm. The term “distance” of nanorods used herein refers to center to center distance unless otherwise stated. In other embodiments, the distance ranges from 5 nm to about 100 nm. The diameter of the nanorods may also vary. In some embodiments, the diameter is at least 5 nm. In other embodiments, the diameter ranges from about 5 nm to about 1 μm. In other embodiments, the diameter ranges from about 5 nm to about 100 nm. The length of the nanorods may also vary. In some embodiments, the length is at least 10 nm. In other embodiments, the length is about 10 nm to about 10 μm.

The composition of the nanorods may also vary. In some embodiments, the nanorods comprise a semiconductor. A variety of semiconductors may be used, including, but not limited to doped or undoped titanium oxide, metatitanic acid, orthotitanic acid, titanium hydroxide, zinc oxide, tungsten oxide, tin oxide, antimony oxide, niobium oxide, indium oxide, barium titanate, strontium titanate, and cadmium sulfide. A variety of forms of titanium oxide may be used, including, but not limited to anatase-form titanium oxide, rutile-form titanium oxide, amorphous titanium oxide, hydrated titanium oxide, and combinations thereof.

The orientation of nanowires on the substrate is epitaxial with the substrate. The term “epitaxial” as used herein refers to an oriented overgrowth of crystalline material upon the surface of another crystal of different chemical composition, but similar structure. In some embodiments, the orientation of nanowires on the substrate may be substantially perpendicular to the surface of the substrate. The orientation of nanowires on the substrate may be substantially perpendicular to the surface of the substrate, but other non-perpendicular orientations to the surface of the substrate may be applied.

The methods disclosed herein are capable of providing nanostructures comprising an array of nanorods disposed on a surface of a crystalline substrate. The surface of the substrate may be lattice-matched to the nanorods and the nanorods may be separated in space from one another. Other characteristics of the nanorods and substrates have been described above. These nanostructures may be incorporated into a device for use in various fields such as electronic, optical and other fields. The nanostructure itself may also provide a photoelectrode. The photoelectrode may be used in a variety of devices, including but not limited to a photovoltaic device, a photoelectrochemical device, and the like. The photoelectrochemical device may be configured for the electrolysis of water to produce hydrogen. In another embodiment, by way of non-limiting example, the photoelectrode may comprise a nanostructure having an array of semiconductor nanorods provided on a surface of a crystalline conducting substrate, wherein a dye is adsorbed on the semiconductor nanorods. The dye may be a dye having an absorption in visible range. Such a photoelectrode may be used for a dye-sensitized solar cell. Devices such as photoelectrodes, photovoltaic devices, photoelectrochemical devices, dye-sensitized solar cells, and other devices incorporating these nanostructures can be fabricated by a person of an ordinary skill in the art by commonly known methods. Discussion of the design, construction and advantages of the devices is disclosed in the references such as Nature 414, 338-344 by Michael Grätzel; Proceedings of the 2001 DOE Hydrogen Program Review, NREL/CP-570-30535 by Eric Miller and Richard Rocheleau; U.S. Pat. No. 4,388,384; EP1643516; J. Am. Chem. Soc. 115 (1993) 6382 by M. Gratzel et al.; J. Am. Chem. Soc., 127 (2005) 16835 by M. Gratzel et al.; Solar Energy Materials and Solar Cells, 32(1994) 259-272 by Smestad et. al.; J. Electrochem. Soc., 151(11), A1767 (2004) by T. Miyasaka, Y. Kijitori; Journal of Photochemistry and Photobiology C: Photochemistry Reviews 4 (2003) 145-153 Review by Michael Grätzel, and the like.

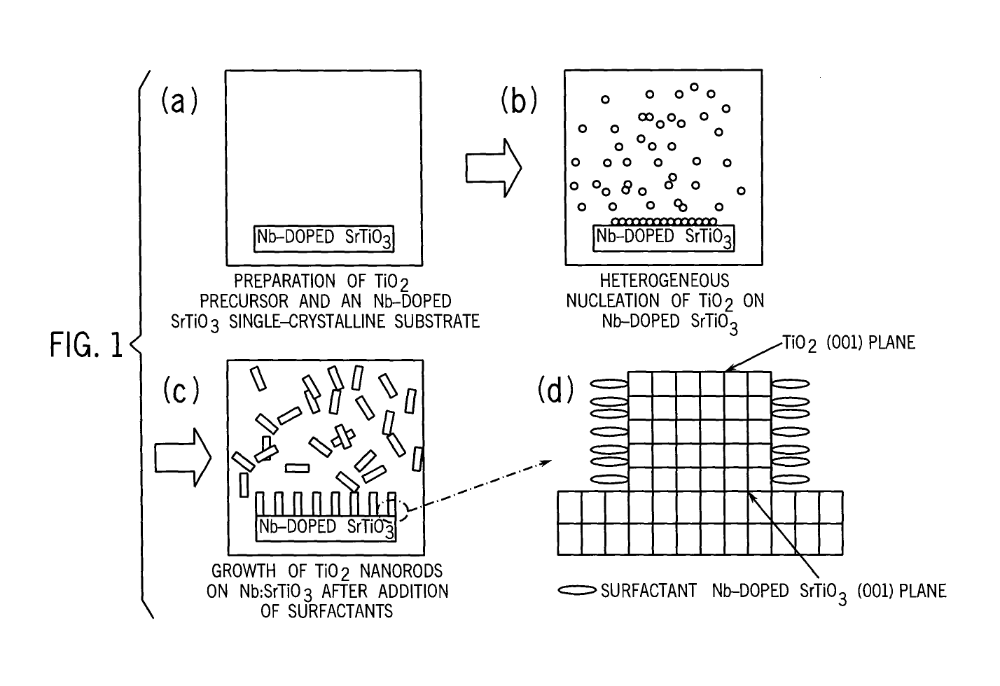

FIG. 1 depicts an illustrative embodiment of a method of forming an array of TiO₂ nanorods on Nb-doped SrTiO₃ substrate: (a) TiO₂ precursors and single crystalline Nb:SrTiO₃ (001) substrates which have an epitaxial relationship with TiO₂ (001) plane are put into a hydrothermal reactor; (b) TiO₂ nanocrystals are heterogeneously nucleated on the Nb:SrTiO₃ (001) substrates after heating the hydrothermal reactor; (c) The addition of surfactant induces the 1-dimensional growth of TiO₂ nanoparticles with <001> direction thereby growing the TiO₂ nanorods on the substrate; (d) Since the TiO₂ nanorods and the Nb:SrTiO₃ (001) substrate have epitaxial relationship, the TiO₂ nanorods are grown with the out-of-plane direction.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

The present embodiments, thus generally described, will be understood more readily by reference to the following examples, which are provided by way of illustration and are not intended to be limiting of the present technology in any way.

### EXAMPLES

The present technology is further illustrated by the following examples, which should not be construed as limiting in any way.

### Example 1

### TiO₂ Nanorod on Nb:SrTiO₂ Substrate

Into a 100 ml-beaker were placed 59.6 g of triethanolamine and 56.8 g of titanium tetraisopropoxide, and the mixture was reacted for 24 hours under stirring. Then, 800 mL of water was added to the mixture to prepare 0.5 M Ti-stock solution. The solution was kept in a refrigerator.

A single crystalline Nb:SrTiO₂ substrate having a (001) surface was put into the solution of 100 mL of the Ti-stock solution, 100 mL of 0.4 M ethylene diamine solution, and 1.5 mL of perch loric acid to form a composition. The composition was placed into an autoclave reactor. The reactor was heated to 100° C. or higher for at least 3 hours to grow nanorods of TiO₂ on the substrate. Then, the reactor was cooled to room temperature, and the nanorods were washed 3 times using 1M NaOH aqueous solution and then three times using 1M HNO₃ aqueous solution to remove the ethylene diamine surfactant. The nanorods were further rinsed three times using de-ionized water. The nanorods were dried and a TEM image thereof was obtained. The TEM image was used to confirm the size and the alignment of the nanorods. The orientation of nanorods on the substrate was substantially perpendicular to the surface of the substrate. The distance between adjacent nanorods was about 5 nm to about 10 nm. The diameter of the nanorods was about 10 nm. The length of nanorods was about 200 nm.

### Example 2

### ZnO Nanorod on a Sapphire (0001) Substrate

Into a 200 mL-beaker are placed 0.7436 g of zinc nitrate hexahydrate, 0.3523 g of hexamethylenetetramine, and 100 ml of water. The mixture is reacted for 24 hours to prepare Zn-stock solution under stirring. The solution is kept in a refrigerator.

100 mL of the Zn-stock solution is combined with a sapphire (0001) substrate to form a composition, which is placed into an autoclave reactor. The reactor is heated to 90° C. or higher for at least 3 hours to grow nanorods of ZnO on the substrate. Then, the reactor is cooled to room temperature, and the ZnO nanorods are washed 3 times using 0.01 M NaOH aqueous solution and then three times using 0.001 M HNO₃ aqueous solution to remove the hexamethylenetetramine surfactant. The nanorods are further rinsed three times using de-ionized water. The nanorods are dried and a TEM image thereof is obtained.

### Example 3

### WO₃ Nanorod on a Sapphire (01-12) Substrate

Into a 200 mL-beaker 0.8 g of tungsten chloride WCl₆, 0.4 g of diethanolamine, and 100 ml of water are combined. The mixture is reacted for 24 hours to prepare W-stock solution under stirring. The solution is kept in a refrigerator.

100 mL of the W-stock solution and 100 mL of 0.4 M ethylene diamine solution are combined with a sapphire (01-12) substrate to form a composition, which is placed into an autoclave reactor. The reactor is heated to 100° C. or higher for at least 3 hours to grow nanorods of WO₃ on the substrate. Then, the reactor is cooled to room temperature, and the WO₃ nanorods are washed 3 times using 0.01 M NaOH aqueous solution and then three times using 0.01 M HNO₃ aqueous solution to remove the ethylene diamine surfactant. The nanorods are further rinsed three times using de-ionized water. The nanorods are dried and a TEM image thereof is obtained.

### Equivalents

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A method of forming an array of nanorods on a crystalline substrate, the method comprising heating a composition comprising the crystalline substrate, a nanorod precursor, and a surfactant, wherein nanorods are formed on the substrate and the surfactant associates with the surface of the nanorods.

2. The method of claim 1, further comprising forming the composition by combining the crystalline substrate with a solution comprising the nanorod precursor and the surfactant.

3. The method of claim 2, further comprising forming the solution by combining the nanorod precursor and the surfactant.

4. The method of claim 1, further comprising removing the surfactant from the surface of the nanorods.

5. The method of claim 1, wherein the heating is carried out in an autoclave reactor.

6. The method of claim 1, wherein the heating is carried out at a temperature of about 90° C. or greater.

7. The method of claim 1, wherein the surface of the substrate is lattice-matched to the nanorods.

8. The method of claim 1, wherein the substrate comprises a conducting metal oxide.

9. The method of claim 8, wherein the conducting metal oxide is selected from the group consisting of SnO₂, CdO, ZnO, indium-tin-oxide (ITO), F:SnO₂ (FTO), Al-doped zinc oxide (AZO), Zn-doped indium oxide (IZO), Ga-doped indium oxide (GZO), Nb:SrTiO₂, sapphire, Nb:TiO₂, (La_{0.5}Sr_{0.5})CoO₃ (LSCO), La_{0.7}Sr_{0.3}MnO₃ (LSMO), SrRuO₃ (SRO), Sr₃Ru₂O₇, and Sr₄Ru₃O₁₀.

10. The method of claim 1, wherein the substrate comprises a semiconductor.

11. The method of claim 10, wherein the semiconductor is selected from the group consisting of undoped or doped titanium oxide, zinc oxide, tungsten oxide, tin oxide, antimony oxide, niobium oxide, indium oxide, barium titanate, strontium titanate, and cadmium sulfide.

12. The method of claim 1, wherein the substrate has a cubic, tetragonal, or orthogonal crystalline lattice.

13. The method of claim 1, wherein the surfactant comprises an amine derivative surfactant.

14. The method of claim 1, wherein the distance between adjacent nanorods ranges from about 5 nm to about 100 nm.

15. The method of claim 1, wherein the diameter of the nanorods ranges from about 5 nm to about 1 μm.

16. The method of claim 1, wherein the length of the nanorods ranges from about 10 nm to about 10 μm.

17. The method of claim 1, wherein the nanorods comprise a semiconductor.

18. The method of claim 17, wherein the semiconductor is selected from the group consisting of undoped or doped titanium oxide, metatitanic acid, orthotitanic acid, titanium hydroxide, zinc oxide, tungsten oxide, tin oxide, antimony oxide, niobium oxide, indium oxide, barium titanate, strontium titanate, and cadmium sulfide.

19. The method of claim 1, wherein the substrate comprises (0001) sapphire and the nanorods comprise ZnO.

20. The method of claim 1, wherein the substrate comprises (01-12) sapphire and the nanorods comprise WO₃.

21. The method of claim 1, wherein the substrate comprises (001) Nb:SrTiO₂ and the nanorods comprise TiO₂.

22. The method of claim 1, further comprising forming a layer of dye on the surface of the nanorods.

23. A composition comprising a crystalline substrate, a nanorod precursor and a surfactant.

24. The composition of claim 23, further comprising an array of nanorods disposed on a surface of the crystalline substrate.

25. The composition of claim 24, wherein the substrate comprises a conducting metal oxide.

26. The composition of claim 25, wherein the conducting metal oxide is selected from the group consisting of SnO₂, CdO, ZnO, indium-tin-oxide (ITO), Al-doped zinc oxide (AZO), Zn-doped indium oxide (IZO), Nb: SrTiO₂, sapphire, Nb:TiO₂, (La_{0.5}Sr_{0.5})CoO₃ (LSCO), La_{0.7}Sr_{0.3}MnO₃ (LSMO), SrRuO₃ (Sr₃Ru₂O₇, and Sr₄Ru₃O₁₀.

27. The composition of claim 26, wherein the nanorods comprise a semiconductor.

28. The composition of claim 27, wherein said semiconductor is selected from the group consisting of doped or undoped titanium oxide, zinc oxide, tungsten oxide, tin oxide, antimony oxide, niobium oxide, indium oxide, barium titanate, strontium titanate, and cadmium sulfide.

29. The composition of claim 27, further comprising a dye adsorbed on the surface of the nanorods.
